(19) United States
(12) Patent Application Publication
(10) Pub. No.: US 2020/0211816 A1
(43) Pub. Date: Jul. 2, 2020

(54) ION IMPLANTER AND MEASURING DEVICE

(71) Applicant: SUMITOMO HEAVY INDUSTRIES ION TECHNOLOGY CO., LTD., Tokyo (JP)

(72) Inventor: Hiroshi Matsushita, Ehime (JP)

(21) Appl. No.: 16/727,547

(22) Filed: Dec. 26, 2019

(30) Foreign Application Priority Data
Dec. 28, 2018 (JP) 2018-247339

(51) Int. Cl. H01J 37/244; H01J 37/14; H01J 37/317

(52) U.S. Cl. CPC H01J 37/244; H01J 37/14; H01J 2237/0206; H01J 2237/24578; H01J 37/3171

(57) ABSTRACT

An ion implanter includes a measuring device that measures an angle distribution of an ion beam with which a wafer is irradiated. The measuring device includes: a slit into which the ion beam is incident; a central electrode body having a beam measurement surface disposed on a central plane extending from the slit to a beam traveling direction; a plurality of side electrode bodies disposed between the slit and the central electrode body and disposed away from the central plane in a slit width direction, in which each of the plurality of side electrode bodies has a beam measurement surface; and a magnet device that applies a magnetic field bending around an axis extending along a slit length direction to at least one of the beam measurement surfaces of the plurality of side electrode bodies.

### RELATED APPLICATIONS

The content of Japanese Patent Application No. 2018-247339, on the basis of which priority benefits are claimed in an accompanying application data sheet, is in its entirety incorporated herein by reference.

### BACKGROUND

### Technical Field

Certain embodiments of the present invention relate to an ion implanter and a measuring device.

### Description of Related Art

In a semiconductor manufacturing process, a process of implanting ions into a semiconductor wafer (also referred to as an ion implantation process) is normally performed in order to change the conductivity of a semiconductor or to change a crystal structure of the semiconductor. It is known that in the ion implantation process, an aspect of interaction between an ion beam and a wafer changes according to an angle of the ion beam with which the wafer is irradiated, and thereby affects ion implantation process results. For this reason, an angle distribution of an ion beam is measured before ion implantation. For example, by measuring current values of a beam which has passed through a slit with a plurality of electrodes arranged in a slit width direction, an angle distribution in the slit width direction is obtained (for example, refer to the related art).

### SUMMARY

According to an aspect of the present invention, there is provided an ion implanter that includes a measuring device that measures an angle distribution of an ion beam with which a wafer is irradiated. The measuring device includes a slit into which the ion beam is incident, a central electrode body that includes a beam measurement surface which is disposed on a central plane extending from the slit to a beam traveling direction, the central plane serving as reference of the ion beam, a plurality of side electrode bodies that are disposed between the slit and the central electrode body and disposed to be away from the central plane in a slit width direction of the slit, in which each of the plurality of side electrode bodies has a beam measurement surface, and a magnet device that applies a magnetic field bending around an axis extending along a slit length direction of the slit to at least one of the beam measurement surfaces of the plurality of side electrode bodies.

According to another aspect of the present invention, there is provided a measuring device. The device is a measuring device that measures an angle distribution of an ion beam. The measuring device includes a slit into which the ion beam is incident, a central electrode body that includes a beam measurement surface which is disposed on a central plane extending from the slit to a beam traveling direction, the central plane serving as reference of the ion beam, a plurality of side electrode bodies that are disposed between the slit and the central electrode body and disposed to be away from the central plane in a slit width direction of the slit, in which each of the plurality of side electrode bodies has a beam measurement surface, and a magnet device that applies a magnetic field bending around an axis extending along a slit length direction of the slit to at least one of the beam measurement surfaces of the plurality of side electrode bodies.

### BRIEF DESCRIPTION OF THE DRAWINGS

FIG. 1 is a top view illustrating a schematic configuration of an ion implanter according to an embodiment.

FIG. 2 is a side view illustrating a schematic configuration of the ion implanter of FIG. 1.

FIG. 3 is an external perspective view illustrating a schematic configuration of a measuring device according to the embodiment.

FIG. 4 is a sectional view illustrating the configuration of the measuring device in detail.

FIG. 5 is a view illustrating a range of a beam measurement surface of each electrode body.

FIG. 6 is a view illustrating an example of a distribution of a magnetic field applied to each electrode body.

FIG. 7 is a view illustrating an example of the distribution of the magnetic field applied to one of side electrode bodies in detail.

FIG. 8 is a view illustrating an example of a distribution of a magnetic field applied to a central electrode body in detail.

### DETAILED DESCRIPTION

When an electrode of a measuring device is irradiated with an ion beam, secondary electrons can be generated from the electrode. When the secondary electrons are generated, a charge amount that is measured changes according to the amount of the generated secondary electrons. Thus, there is a possibility that a measurement error results. For example, in a configuration where a plurality of electrodes are arranged in order to measure an angle distribution, secondary electrons may be incident into an electrode different from an electrode where the secondary electrons are generated, for example, the next electrode. Then, a charge amount measured by each of the electrode where the secondary electrons are generated and the another electrode into which the secondary electrons are incident changes due to the secondary electrons, and thereby a measurement error in an angle distribution results.

It is desirable to provide a technique for preventing a measurement accuracy degradation caused by the generation of secondary electrons.

Any combination of the configuration elements described above, or an embodiment, in which a configuration element or description of the present invention is switched between methods, devices, and systems, is also effective as an aspect of the present invention.

The present invention can improve the measurement accuracy of a beam angle distribution measuring device.

Hereinafter, a form for implementing the present invention will be described in detail with reference to the drawings. The same elements in each drawing will be assigned with the same reference signs, and overlapping description thereof will be omitted as appropriate. In addition, configurations to be described below are examples, and do not limit the scope of the present invention.

An outline will be described before elaborating the embodiment in detail. In the embodiment, an ion implanter includes a measuring device that measures an angle distribution of an ion beam with which a wafer is irradiated. The measuring device includes a slit into which the ion beam is incident, a central electrode body that includes a beam measurement surface which is disposed on a central plane extending from the slit to a beam traveling direction, the central plane serving as reference of the ion beam, a plurality of side electrode bodies that are disposed between the slit and the central electrode body and disposed to be away from the central plane in a slit width direction of the slit, in which each of the plurality of side electrode bodies has a beam measurement surface, and a magnet device that applies a magnetic field bending around an axis extending along a slit length direction of the slit to at least one of the beam measurement surfaces of the plurality of side electrode bodies. In the embodiment, a measurement accuracy degradation attributable to a secondary electron, which is generated by the ion beam being incident into the beam measurement surface, can be suitably prevented by applying an appropriate magnetic field to the beam measurement surface of the side electrode body.

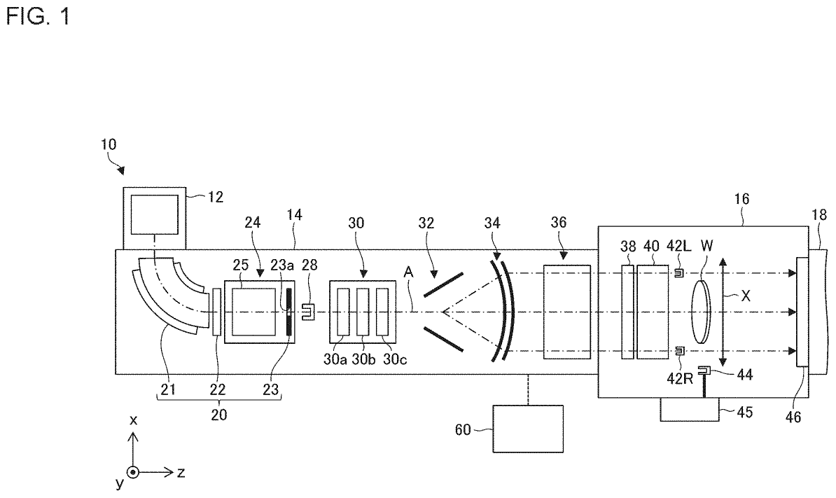

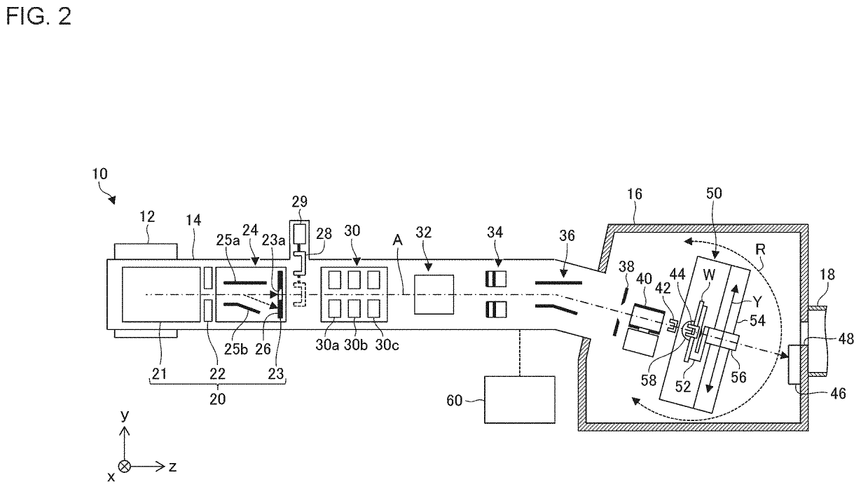

FIG. 1 is a top view schematically illustrating an ion implanter 10 according to the embodiment, and FIG. 2 is a side view illustrating a schematic configuration of the ion implanter 10. The ion implanter 10 is configured to perform ion implantation process onto a surface of an object to be processed W. The object to be processed W is, for example, a substrate, or for example, a semiconductor wafer. Although the object to be processed W is called a wafer W in some cases in the disclosure for convenience of description, it does not intend to limit a target of the implantation process to a specific object.

The ion implanter 10 is configured such that an entire processing surface of the wafer W is irradiated with an ion beam by scanning the beam reciprocatingly in one direction and reciprocating the wafer W in another direction perpendicular to the scanning direction. For convenience of description, a traveling direction of an ion beam that travels along a beamline A in terms of design will be defined as a z-direction, and a plane perpendicular to the z-direction will be defined as an xy-plane in the disclosure. In a case where an ion beam scans the object to be processed W, the scanning direction of the beam will be referred to as an x-direction, and a direction perpendicular to both the z-direction and the x-direction will be referred to as a y-direction. Therefore, beam reciprocating scanning is performed in the x-direction, and the reciprocation of the wafer W is performed in the y-direction.

The ion implanter 10 includes an ion source 12, a beamline device 14, an implantation process chamber 16, and a wafer transfer device 18. The ion source 12 is configured to supply an ion beam to the beamline device 14. The beamline device 14 is configured to transport the ion beam from the ion source 12 to the implantation process chamber 16. In the implantation process chamber 16, the wafer W, which is an implanting target, is accommodated, and implantation process in which the wafer W is irradiated with the ion beam supplied from the beamline device 14 is performed. The wafer transfer device 18 is configured to take an unprocessed wafer before implantation process into the implantation process chamber 16, and to take the processed wafer after implantation process out from the implantation process chamber 16. The ion implanter 10 includes evacuation systems (not illustrated) for providing the ion source 12, the beamline device 14, the implantation process chamber 16, and the wafer transfer device 18 with desired vacuum environments.

The beamline device 14 includes, in order from an upstream side of the beamline A, a mass analyzing unit 20, a beam park device 24, a beam shaping unit 30, a beam scanning unit 32, a beam parallelizing unit 34, and an angular energy filter (AEF) 36. The upstream side of the beamline A refers to a side close to the ion source 12, and the downstream side of the beamline A refers to aside close to the implantation process chamber 16 (or a beam stopper 46).

The mass analyzing unit 20 is provided on the downstream side of the ion source 12, and is configured to select a necessary ion species from an ion beam extracted from the ion source 12 based on mass analysis. The mass analyzing unit 20 includes a mass analyzing magnet 21, a mass analyzing lens 22, and a mass analyzing slit 23.

The mass analyzing magnet 21 applies a magnetic field to the ion beam extracted from the ion source 12, and deflects the ion beam along a path that differs according to a value of an ion mass to charge ratio M=m/q (m is mass, and q is charge). The mass analyzing magnet 21 applies, for example, a magnetic field in the y-direction (for example, a −y-direction) to the ion beam, and deflects the ion beam in the x-direction. A strength of a magnetic field applied by the mass analyzing magnet 21 is adjusted such that an ion species having a desired ion mass to charge ratio M passes through the mass analyzing slit 23.

The mass analyzing lens 22 is provided on the downstream side of the mass analyzing magnet 21, and is configured to adjust a converging/diverging force with respect to the ion beam. The mass analyzing lens 22 adjusts a focusing position of the ion beam passing through the mass analyzing slit 23 in the beam traveling direction (z-direction), and adjusts mass resolution M/dM of the mass analyzing unit 20. The mass analyzing lens 22 is not an essential component, and the mass analyzing lens 22 may not be provided in the mass analyzing unit 20.

The mass analyzing slit 23 is provided on the downstream side of the mass analyzing lens 22, and is provided at a position away from the mass analyzing lens 22. The mass analyzing slit 23 is configured such that a beam deflecting direction (x-direction) by the mass analyzing magnet 21 becomes a slit width direction, and includes an opening 23a having a shape that is relatively small in the x-direction and is relatively large in the y-direction.

The mass analyzing slit 23 may be configured such that the slit width is variable for the sake of the adjustment of mass resolution. The mass analyzing slit 23 may be configured with two shielding bodies that are movable in the slit width direction, and may be configured such that the slit width is adjustable by changing an interval between the two shielding bodies. The mass analyzing slit 23 may be configured such that the slit width is variable by switching to any one of a plurality of slits having slit widths different from each other.

The beam park device 24 is configured to allow an ion beam to be temporarily retracted from the beamline A and to block the ion beam directed toward the implantation process chamber 16 (or the wafer W) on the downstream side. Although the beam park device 24 can be disposed at any position on the way of the beamline A, the beam park device is disposed, for example, between the mass analyzing lens 22 and the mass analyzing slit 23. Since a sufficient distance is necessary between the mass analyzing lens 22 and the mass analyzing slit 23, the beam park device 24 can be provided therebetween. As a result, a length of the beamline A can be made shorter, and the entire ion implanter 10 can be miniaturized more than a case of disposing the beam park device at another position.

The beampark device 24 includes a pair of park electrodes 25 (25a and 25b) and a beam dump 26. The pair of park electrodes 25a and 25b face each other with the beamline A interposed therebetween, and face each other in a direction (y-direction) perpendicular to the beam deflecting direction (x-direction) of the mass analyzing magnet 21. The beam dump 26 is provided closer to the downstream side along the beamline A than the park electrodes 25a and 25b are, and is provided away from the beamline A in an facing direction of the park electrodes 25a and 25b.

The first park electrode 25a is disposed above the beamline A in a gravity direction, and the second park electrode 25b is disposed below the beamline A in the gravity direction. The beam dump 26 is provided at a position lower than the beamline A in the gravity direction, and is disposed below the opening 23a of the mass analyzing slit 23 in the gravity direction. The beam dump 26 is configured in, for example, a portion in which the opening 23a of the mass analyzing slit 23 is not formed. The beam dump 26 may be configured as a body separate from the mass analyzing slit 23.

The beam park device 24 deflects an ion beam by using an electric field applied between the pair of park electrodes 25a and 25b, and allows the ion beam to be retracted from the beamline A. For example, by applying a negative voltage to the second park electrode 25b with an electric potential of the first park electrode 25a as reference, the ion beam is deflected downwards from the beamline A in the gravity direction and is incident into the beam dump 26. In FIG. 2, a trajectory of the ion beam directed toward the beam dump 26 is shown with a dashed line. In addition, the beam park device 24 allows the ion beam to pass through to the downstream side along the beamline A by making the electric potentials of the pair of park electrodes 25a and 25b the same. The beam park device 24 is configured to be capable of being operated by switching between a first mode in which an ion beam passes through to the downstream side and a second mode in which an ion beam is incident into the beam dump 26.

An injector Faraday cup 28 is provided on the downstream side of the mass analyzing slit 23. The injector Faraday cup 28 is configured to be movable into or out of the beamline A by an operation of the injector drive unit 29. The injector drive unit 29 moves the injector Faraday cup 28 in a direction (for example, the y-direction) perpendicular to a direction where the beamline A extends. The injector Faraday cup 28 blocks an ion beam directed toward the downstream side in a case where the injector Faraday cup is disposed on the beamline A as shown with the dashed line in FIG. 2. On the other hand, the blocking of the ion beam directed toward the downstream side is released in a case where the injector Faraday cup 28 is shifted away from the beamline A as shown with a solid line in FIG. 2.

The injector Faraday cup 28 is configured to measure a beam current of the ion beam which has undergone mass analysis by the mass analyzing unit 20. The injector Faraday cup 28 can measure a mass analysis spectrum of the ion beam by measuring a beam current while changing a strength of a magnetic field applied by the mass analyzing magnet 21. By using the measured mass analysis spectrum, the mass resolution of the mass analyzing unit 20 can be calculated.

The beam shaping unit 30 includes a focusing/defocusing lens such as a quadrupole focusing/defocusing device (Q lens), and is configured to shape the ion beam which has passed through the mass analyzing unit 20 into a desired cross-sectional shape. The beam shaping unit 30 is configured as, for example, an electric field type three-stage quadrupole lens (also referred to as a triplet Q lens), and includes three quadrupole lenses 30a, 30b, and 30c. The beam shaping unit 30 can independently adjust the converging or diverging of the ion beam in each of the x-direction and the y-direction by using the three quadrupole lenses 30a to 30c. The beam shaping unit 30 may include a magnetic field type lens device, or may include a lens device that shapes a beam by using both an electric field and a magnetic field.

The beam scanning unit 32 is a beam deflecting device that is configured to provide beam reciprocating scanning, and causes a shaped ion beam to scan the object to be processed in the x-direction. The beam scanning unit 32 has a pair of scanning electrodes that face each other in a beam scanning direction (x-direction). The pair of scanning electrodes are connected to a variable voltage power supply (not illustrated). By periodically changing a voltage applied between the pair of scanning electrodes, an electric field generated between the electrodes is changed to deflect an ion beam in various angles. As a result, the ion beam is caused to perform scanning over an entire scanning range in the x-direction. In FIG. 1, the beam scanning direction and the scanning range are shown with an arrow X, and a plurality of trajectories of the ion beam in the scanning range are shown with one-dot chain lines.

The beam parallelizing unit 34 is configured to make the traveling direction of the ion beam, which has performed scanning, parallel to a trajectory of the beamline A in terms of design. The beam parallelizing unit 34 includes a plurality of arc-shaped parallelizing lens electrodes each of which has a central portion where an ion beam passing slit is provided. The parallelizing lens electrodes are connected to a high-voltage power supply (not illustrated), and the traveling direction of the ion beam is made parallel by exerting an electric field generated by voltage application to the ion beam. The beam parallelizing unit 34 may be replaced with another beam parallelizing device, and the beam parallelizing device may be configured as a magnet device in which a magnetic field is used.

An accel/decel (AD) column (not illustrated) for accelerating or decelerating an ion beam may be provided on the downstream side of the beam parallelizing unit 34.

The angular energy filter (AEF) 36 is configured to analyze the energy of an ion beam by deflecting ions which have necessary energy downward and to lead the ions to the implantation process chamber 16. The angular energy filter 36 includes a pair of AEF electrodes for deflection by an electric field. The pair of AEF electrodes are connected to the high-voltage power supply (not illustrated). In FIG. 2, an ion beam is deflected downwards by applying a positive voltage to the upper AEF electrode and a negative voltage to the lower AEF electrode. The angular energy filter 36 may be configured by a magnet device for deflection with a magnetic field, or may be configured by combining a pair of AEF electrodes for deflection by an electric field with a magnet device.

In this manner, the beamline device 14 supplies an ion beam with which the wafer W is irradiated to the implantation process chamber 16.

The implantation process chamber 16 includes, in order from the upstream side of the beamline A, an energy slit 38, a plasma shower device 40, a side cup 42, a center cup 44, and the beam stopper 46. The implanting process chamber 16 includes a platen drive device 50 that holds one or a plurality of wafers W as illustrated in FIG. 2.

The energy slit 38 is provided on the downstream side of the angular energy filter 36, and performs, along with the angular energy filter 36, energy analysis of an ion beam incident into the wafer W. The energy slit 38 is an energy defining slit (EDS) configured by a slit which is horizontally long in the beam scanning direction (x-direction). The energy slit 38 allows an ion beam having a desired energy value or a desired energy range to pass through toward the wafer W, and blocks other ion beams.

The plasma shower device 40 is positioned on the downstream side of the energy slit 38. The plasma shower device 40 supplies low-energy electrons to an ion beam and a surface (wafer processing surface) of the wafer W according to a beam current of the ion beam, and suppresses charge-up of positive charge on the wafer processing surface, which occurs due to ion implantation. The plasma shower device 40 includes, for example, a shower tube through which an ion beam passes and a plasma generating device that supplies electrons into the shower tube.

The side cup 42 (42R and 42L) is configured to measure a beam current of an ion beam while ion implantation process to the wafer W is performed. As illustrated in FIG. 2, the side cups 42R and 42L are disposed to be deviated to the right and the left (in the x-direction) with respect to the wafer W disposed on the beamline A, and are disposed at positions at which the side cups 42R and 42L do not block the ion beam directed toward the wafer W during ion implantation. Since the ion beam is caused to perform scanning in the x-direction beyond a range where the wafer W is positioned, apart of the beam, which performs scanning, is incident into the side cups 42Rand 42L during ion implantation. Accordingly, the beam current during ion implantation process is measured by the side cup 42R and 42L.

The center cup 44 is configured to measure a beam current on the wafer processing surface. The center cup 44 is configured to be movable by an operation of a drive unit 45, is retracted from an implanting position where the wafer W is positioned during ion implantation, and is inserted to the implanting position when the wafer W is not at the implanting position. The center cup 44 can measure a beam current over an entire beam scanning range in the x-direction by measuring the beam current while moving in the x-direction. A plurality of Faraday cups may be formed as the center cup 44 to be arranged in an array in the x-direction such that the center cup 44 can simultaneously measure a beam current at a plurality of positions in the beam scanning direction (x-direction).

At least one of the side cup 42 and the center cup 44 may include a single Faraday cup for measuring a beam current, or may include an angle measuring instrument for obtaining angle information of a beam. The angle measuring instrument includes, for example, a slit and a plurality of current detecting elements provided to be away from the slit in the beam traveling direction (z-direction). For example, by the plurality of current detecting elements arranged in the slit width direction and measuring a beam which has passed through the slit, an angle component of the beam in the slit width direction can be measured. At least one of the side cup 42 and the center cup 44 may include a first angle measuring instrument that can obtain angle information in the x-direction and a second angle measuring instrument that can obtain angle information in the y-direction.

The platen drive device 50 includes a wafer holding device 52, a reciprocating mechanism 54, a twist angle adjusting mechanism 56, and a tilt angle adjusting mechanism 58. The wafer holding device 52 includes an electrostatic chuck or the like for holding the wafer W. The reciprocating mechanism 54 reciprocates a wafer held by the wafer holding device 52 in the y-direction by reciprocating the wafer holding device 52 in a reciprocating direction (y-direction) perpendicular to the beam scanning direction (x-direction). In FIG. 2, the reciprocation of the wafer W is shown with an arrow Y.

The twist angle adjusting mechanism 56 is a mechanism that adjusts a rotation angle of the wafer W, and adjusts a twist angle between an alignment mark provided on an outer circumferential portion of the wafer and a reference position by rotating the wafer W with a normal line of the wafer processing surface as an axis. Herein, the alignment mark of the wafer refers to a notch or an orientation flat provided on the outer circumferential portion of the wafer, and refers to a mark that serves as reference for an angular position in a crystal axis direction of the wafer or in a circumferential direction of the wafer. The twist angle adjusting mechanism 56 is provided between the wafer holding device 52 and the reciprocating mechanism 54, and is reciprocated together with the wafer holding device 52.

The tilt angle adjusting mechanism 58 is a mechanism that adjusts an inclination of the wafer W, and adjusts a tilt angle between the traveling direction of an ion beam directed toward the wafer processing surface and the normal line of the wafer processing surface. In the embodiment, out of inclination angles of the wafer W, an angle, of which a central axis of rotation is an axis along the x-direction, is adjusted as the tilt angle. The tilt angle adjusting mechanism 58 is provided between the reciprocating mechanism 54 and an inner wall of the implantation process chamber 16, and is configured to adjust the tilt angle of the wafer W by rotating the entire platen drive device 50, including the reciprocating mechanism 54, in an R-direction.

The platen drive device 50 holds the wafer W such that the wafer W is movable between the implanting position where the wafer W is irradiated with an ion beam and a transfer position where the wafer W is taken in or taken out between the wafer transfer device 18 and the platen drive device 50. FIG. 2 illustrates a state where the wafer W is at the implanting position, and the platen drive device 50 holds the wafer W such that the beamline A and the wafer W intersect each other. The transfer position of the wafer W corresponds to a position of the wafer holding device 52 when the wafer W is taken in or taken out through a transfer port 48 by a transfer mechanism or a transfer robot provided in the wafer transfer device 18.

The beam stopper 46 is provided on the most downstream side along the beamline A, and is mounted on, for example, an inner wall of the implantation process chamber 16. In a case where the wafer W does not exist on the beamline A, an ion beam is incident into the beam stopper 46. The beam stopper 46 is positioned close to the transfer port 48 that connects the implantation process chamber 16 to the wafer transfer device 18, and is provided at a position vertically below the transfer port 48.

The ion implanter 10 includes a central control device 60. The central control device 60 controls an overall operation of the ion implanter 10. The central control device 60 can be realized by an element such as a CPU or a memory of computer or a mechanical device in terms of hardware, and can be realized by a computer program or the like in terms of software. Various functions provided through the central control device 60 can be realized by cooperation between hardware and software.

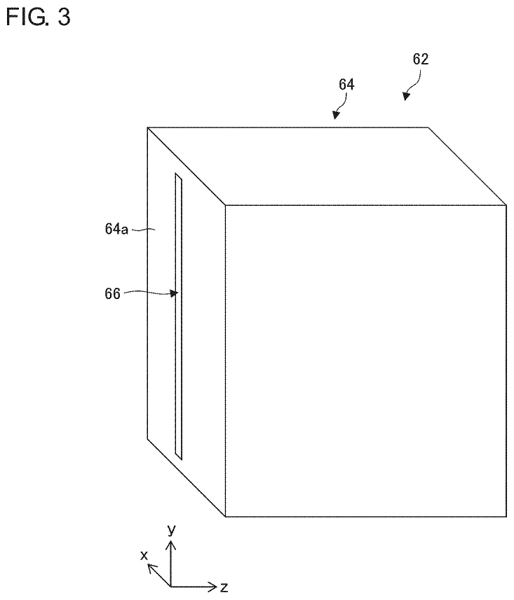

FIG. 3 is an external perspective view illustrating a schematic configuration of a measuring device 62 according to the embodiment. The measuring device 62 includes a housing 64 and a slit 66 provided in a front surface 64a of the housing 64. A plurality of electrode bodies are provided inside the housing 64. The measuring device 62 is a device for measuring an angle distribution of an ion beam, detects the ion beam having passed through the slit 66 with the plurality of electrode bodies, and acquires the angle distribution of the ion beam based on detection results of each electrode body. The measuring device 62 can be used by being disposed at, for example, a position of the side cup 42 or the center cup 44 in the ion implanter 10 described above.

In the examples shown, the traveling direction of an ion beam is set as the z-direction, the slit width direction of the slit 66 is set as the x-direction, the slit length direction of the slit 66 is set as the y-direction, and the measuring device 62 is configured to measure an angle distribution in the x-direction. A direction where the measuring device 62 measures the angle distribution is not limited to the x-direction, and the measuring device 62 may be used such that an angle distribution in the y-direction can be measured. In addition, the measuring device 62 may be used such that an angle distribution in a direction oblique to both the x-direction and the y-direction can be measured.

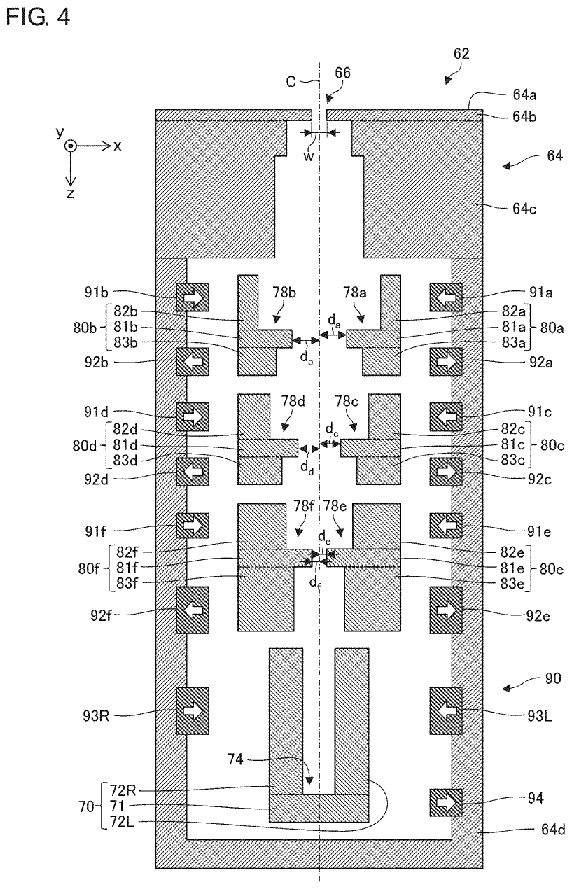

FIG. 4 is a sectional view illustrating a configuration of the measuring device 62 in detail, and illustrates a structure of a section (xz-plane) perpendicular to the slit length direction of the slit 66 (y-direction). The measuring device 62 includes the housing 64, a central electrode body 70, a plurality of side electrode bodies 80a, 80b, 80c, 80d, 80e, and 80f (also collectively referred to as a side electrode body 80), and a magnet device 90.

The housing 64 includes a slit portion 64b, an angle restricting unit 64c, and an electrode accommodating unit 64d. The slit portion 64b includes the front surface 64a in which the slit 66 is provided. The angle restricting unit 64c is provided on the downstream side of the slit portion 64b in the beam traveling direction (z-direction). The angle restricting unit 64c blocks a part of an ion beam directed toward the side electrode body 80 (for example, the first side electrode body 80a and the second side electrode body 80b) such that a beam having an angle component out of a measuring range is not incident into the side electrode body 80. The electrode accommodating unit 64d is provided on the downstream side of the angle restricting unit 64c in the beam traveling direction (z-direction). The electrode accommodating unit 64d is configured to include a yoke for forming a magnetic circuit of the magnet device 90.

The central electrode body 70 is disposed on a central plane C extending from the slit 66 to the beam traveling direction (z-direction), and is disposed on the most downstream side which is away from the slit 66 in the beam traveling direction. Abeam of which an angle component in the slit width direction (x-direction) is zero or extremely small, that is, a beam that travels almost straight along the central plane C without being incident into the plurality of side electrode bodies 80a to 80f is a measuring target of the central electrode body 70.

The central electrode body 70 includes a base portion 71 and a pair of extending portions 72L and 72R. The base portion 71 is disposed on the central plane C. The base portion 71 includes a beam measurement surface 74 that is exposed to the slit 66 along the beam traveling direction. The pair of extending portions 72L and 72R respectively extend from both ends of the base portion 71 in the slit width direction (x-direction) to the upstream side in the beam traveling direction (z-direction).

The plurality of side electrode bodies 80a to 80f are disposed between the slit 66 and the central electrode body 70, and are disposed to be symmetrical to each other in the slit width direction (x-direction) with the central plane C interposed therebetween. In the examples shown, six side electrode bodies 80a to 80f are provided. A pair of three side electrode bodies are provided on both sides with the central plane C interposed therebetween. Specifically, the first side electrode body 80a and the second side electrode body 80b are disposed to be symmetrical to each other in the slit width direction (x-direction) with the central plane C interposed therebetween, the third side electrode body 80c and the fourth side electrode body 80d are disposed to be symmetrical to each other in the slit width direction (x-direction) with the central plane C interposed therebetween, and the fifth side electrode body 80e and the sixth side electrode body 80f are disposed to be symmetrical to each other in the slit width direction (x-direction) with the central plane C interposed therebetween.

The first side electrode body 80a, the third side electrode body 80c, and the fifth side electrode body 80e configure a first group of side electrode bodies arranged in the beam traveling direction (z-direction). The second side electrode body 80b, the fourth side electrode body 80d, and the sixth side electrode body 80f configure a second group of side electrode bodies arranged in the beam traveling direction (z-direction). The second group of side electrode bodies 80b, 80d, and 80f is disposed to be symmetrical to the first group of side electrode bodies 80a, 80c, and 80d in the slit width direction (x-direction) with the central plane C interposed therebetween.

Distances dₐ, d_{b}, d_{c}, d_{d}, dₑ, and d_{f} from the central plane C to the plurality of side electrode bodies 80a to 80f in the slit width direction (x-direction) become smaller as the side electrode bodies are disposed closer to the downstream side in the beam traveling direction. The respective distances dₐ and d_{b} from the central plane C to the first side electrode body 80a and the second side electrode body 80b are relatively large. For example, the distances are 1.5 times a slit width w of the slit 66. The respective distances d_{c} and d_{d} from the central plane C to the third side electrode body 80c and the fourth side electrode body 80d are medium. For example, the distances are 1 time (that is, the same as) the slit width w of the slit 66. The respective distances dₑ and d_{f} from the central plane C to the fifth side electrode body 80e and the sixth side electrode body 80f are relatively small. For example, the distances are 0.5 times the slit width w of the slit 66.

The plurality of side electrode bodies 80a to 80f have main body portions 81a, 81b, 81c, 81d, 81e, and 81f (also collectively referred to as a main body portion 81), upstream side extending portions 82a, 82b, 82c, 82d, 82e, and 82f (also collectively referred to as an upstream side extending portion 82), and downstream side extending portions 83a, 83b, 83c, 83d, 83e, and 83f (also collectively referred to as a downstream side extending portion 83), respectively. The plurality of side electrode bodies 80a to 80f respectively include beam measurement surfaces 78a, 78b, 78c, 78d, 78e, and 78f (also collectively referred to as a beam measurement surface 78) into which a beam having passed through the slit 66 is incident.

The main body portion 81 is a portion that protrudes toward the central plane C in the slit width direction (x-direction). Therefore, a distance from the central plane C to the main body portion 81 (for example, the distance dₐ) is smaller than a distance from the central plane C to the upstream side extending portion 82 or a distance from the central plane to the downstream side extending portion 83. The main body portion 81 is a portion into which a beam having passed through the slit 66 is mainly incident. Therefore, a surface of at least a part of the main body portion 81 configures at least a part of the beam measurement surface 78 of the side electrode body 80.

The upstream side extending portion 82 is a portion extending from the main body portion 81 to the upstream side. The upstream side extending portion 82 is provided to be further away from the central plane C in the slit width direction (x-direction) than the main body portion 81 is. The downstream side extending portion 83 is a portion extending from the main body portion 81 to the downstream side. The downstream side extending portion 83 is provided to be further away from the central plane C in the slit width direction (x-direction) than the main body portion 81 is. A length of each of the upstream side extending portion 82 and the downstream side extending portion 83 in the beam traveling direction (z-direction) is larger than a length of the main body portion 81 in the beam traveling direction (z-direction).

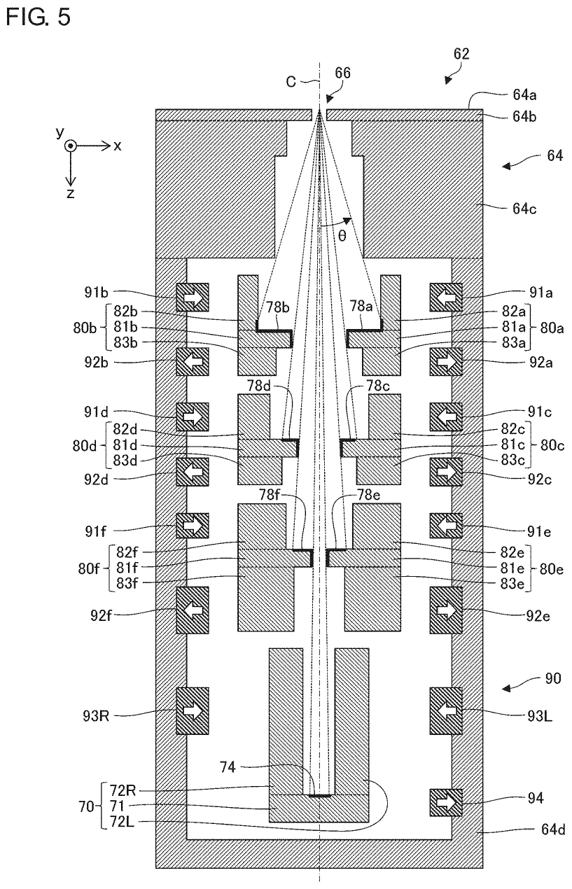

FIG. 5 is a view illustrating respective ranges of the beam measurement surfaces 74 and 78 of the electrode bodies 70 and 80. In FIG. 5, the ranges of the beam measurement surface 74 of the central electrode body 70 and the beam measurement surface 78 of each of the plurality of side electrode bodies 80 are shown with thick lines. The range of the beam measurement surface of each electrode body is a range of a surface of each electrode body into which a beam having passed through the slit 66 can be incident.

Out of beams having passed through the slit 66, a beam of which an angle component in the slit width direction (x-direction) is larger than θ is incident into an inner surface of the angle restricting unit 64c of the housing 64. As a result, the beam of which the angle component in the slit width direction (x-direction) is larger than θ is not detected by the electrode bodies, and is out of a measuring range of the measuring device 62. On the contrary, a beam of which an angle component in the slit width direction (x-direction) is equal to or smaller than 0 is incident into any one of the central electrode body 70 and the plurality of side electrode bodies 80.

A beam of which an angle component is relatively large can be incident into the first beam measurement surface 78a of the first side electrode body 80a or the second beam measurement surface 78b of the second side electrode body 80b. The first beam measurement surface 78a is configured by a part of a surface of the first main body portion 81a and a part of a surface of the first upstream side extending portion 82a. On the other hand, a beam having passed through the slit 66 is not incident into a surface of the first downstream side extending portion 83a. That is because the surface of the first downstream side extending portion 83a is positioned behind the first main body portion 81a protruding toward the central plane C, when seen from the slit 66. The first beam measurement surface 78a may be configured by only a part of the surface of the first main body portion 81a, and a beam having passed through the slit 66 may not be incident into the surface of the first upstream side extending portion 82a. The second beam measurement surface 78b is configured to be symmetrical to the first beam measurement surface 78a in the slit width direction with the central plane C interposed therebetween.

A beam of which an angle component is medium can be incident into the third beam measurement surface 78c of the third side electrode body 80c or the fourth beam measurement surface 78d of the fourth side electrode body 80d. The third beam measurement surface 78c is configured by a part of a surface of the third main body portion 81c. On the other hand, a beam having passed through the slit 66 is not incident into surfaces of the third upstream side extending portion 82c and the third downstream side extending portion 83c. That is because the surface of the third upstream side extending portion 82c is positioned behind the first side electrode body 80a, and the surface of the third downstream side extending portion 83c is positioned behind the third main body portion 81c protruding toward the central plane C, when seen from the slit 66. A part of the surface of the third upstream side extending portion 82c may be configured to be the third beam measurement surface 78c. The fourth beam measurement surface 78d is configured to be symmetrical to the third beam measurement surface 78c in the slit width direction with the central plane C interposed therebetween.

A beam of which an angle component is relatively small can be incident into the fifth beam measurement surface 78e of the fifth side electrode body 80e or the sixth beam measurement surface 78f of the sixth side electrode body 80f. The fifth beam measurement surface 78e is configured by a part of a surface of the fifth main body portion 81e. On the other hand, a beam having passed through the slit 66 is not incident into surfaces of the fifth upstream side extending portion 82e and the fifth downstream side extending portion 83e. That is because the surface of the fifth upstream side extending portion 82e is positioned behind the third side electrode body 80c, and the surface of the fifth downstream side extending portion 83e is positioned behind the fifth main body portion 81e protruding toward the central plane C, when seen from the slit 66. A part of the surface of the fifth upstream side extending portion 82e may be configured to be the fifth beam measurement surface 78e. The sixth beam measurement surface 78f is configured to be symmetrical to the fifth beam measurement surface 78e in the slit width direction with the central plane C interposed therebetween.

A beam of which an angle component is almost zero can be incident into the beam measurement surface 74 of the central electrode body 70. The beam measurement surface 74 of the central electrode body 70 is configured by a part of a surface of the base portion 71 of the central electrode body 70. At least a part of inner surfaces of the extending portions 72L and 72R of the central electrode body 70 may be configured as the beam measurement surface 74.

The magnet device 90 is configured to apply a magnetic field to the beam measurement surfaces 74 and 78 of the central electrode body 70 and each of the plurality of side electrode bodies 80. The magnet device 90 includes a plurality of first magnets 91a, 91b, 91c, 91d, 91e, and 91f (also collectively referred to as a first magnet 91), a plurality of second magnets 92a, 92b, 92c, 92d, 92e, and 92f (also collectively referred to as a second magnet 92), two third magnets 93L and 93R (also collectively referred to as a third magnet 93), and one fourth magnet 94. Each of the magnets 91 to 94 is disposed to be further away from the central plane C in the slit width direction (x-direction) than the central electrode body 70 and the plurality of side electrode bodies 80 are. Each of the magnets 91 to 94 is disposed along an inner wall surface of the electrode accommodating unit 64d of the housing 64. Each of illustrated arrows schematically shows a magnetization direction of each of the magnets 91 to 94.

The first magnet 91 and the second magnet 92 are configured to have polarities opposite to each other. The first magnet 91 has, for example, a first magnetic pole, which is an N-pole, and is disposed such that the first magnetic pole is directed to an inner side. The second magnet 92 has, for example, a second magnetic pole, which is an S-pole, and is disposed such that the second magnetic pole is directed to an inner side. Similarly, the third magnet 93 and the fourth magnet 94 are configured to have polarities opposite to each other. The third magnet 93 has, for example, a third magnetic pole, which is an N-pole, and is disposed such that the third magnetic pole is directed to an inner side. The fourth magnet 94 has, for example, a fourth magnetic pole, which is an S-pole, and is disposed such that the fourth magnetic pole is directed to an inner side. The first magnetic pole and the third magnetic pole each may be the S-pole, and the second magnetic pole and the fourth magnetic pole each may be the N-pole.

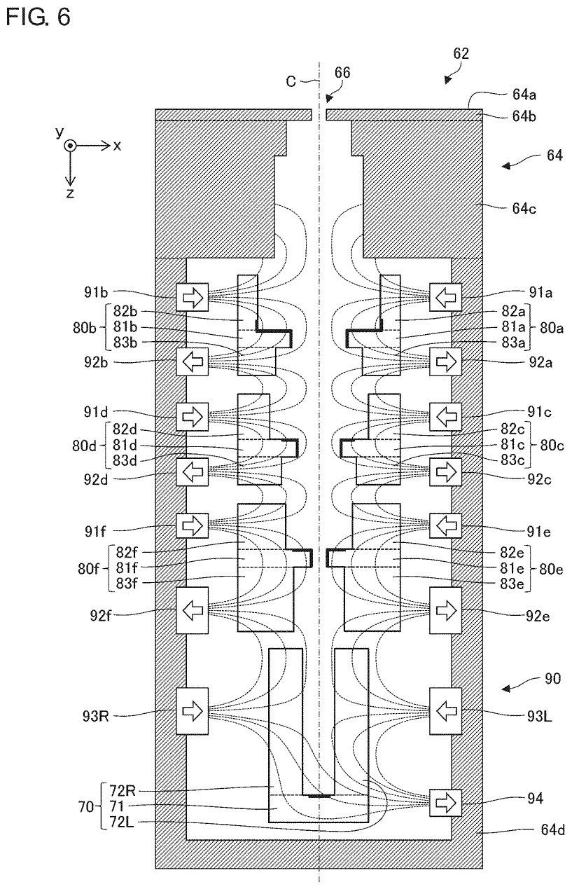

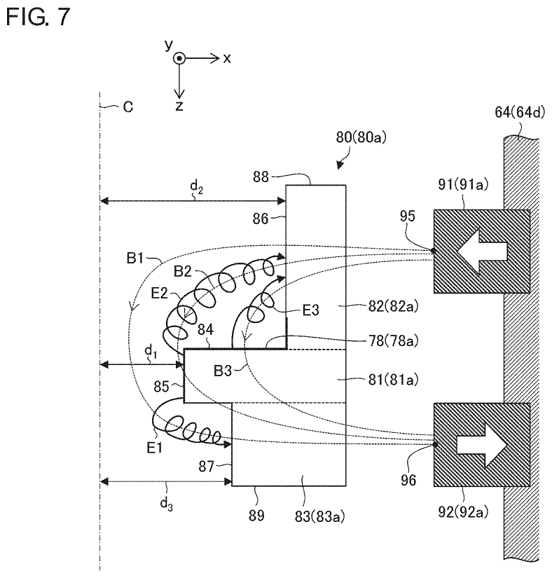

The plurality of first magnets 91 and the plurality of second magnets 92 are disposed along the inner wall surface of the electrode accommodating unit 64d of the housing 64 to be alternately arranged in the beam traveling direction, and a pair of the first magnet 91 and the second magnet 92 are disposed to correspond to each of the plurality of side electrode bodies 80a to 80f. For example, the pair of the first magnet 91a and the second magnet 92a is disposed in a vicinity of the first side electrode body 80a. The first magnet 91 is disposed on the upstream side of the main body portion 81 of the corresponding side electrode body 80, and the second magnet 92 is disposed on the downstream side of the main body portion 81 of the corresponding side electrode body 80. The first magnet 91 and the second magnet 92 apply a magnetic field bending around an axis extending in the slit length direction (y-direction) of the slit 66 to the beam measurement surface 78 of the corresponding side electrode body 80 (refer to FIGS. 6 and 7 to be described later). The plurality of first magnets 91 and the plurality of second magnets 92 are disposed to be symmetrical to each other in the slit width direction (x-direction) with the central plane C interposed therebetween, and apply a magnetic field having a symmetrical distribution in the slit width direction (x-direction) with respect to the central plane C.

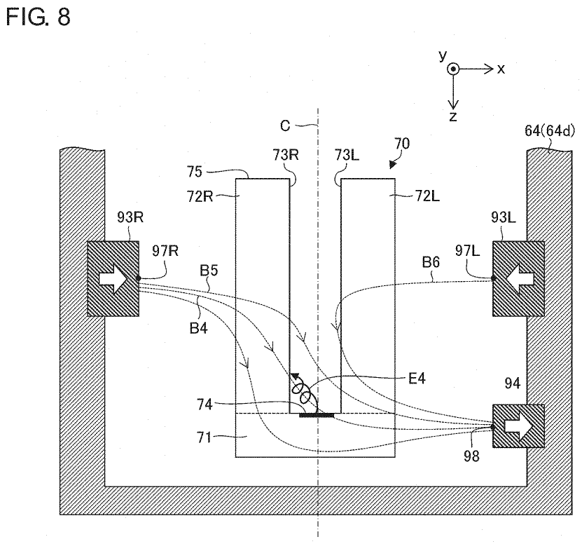

The two third magnets 93L and 93R and the fourth magnet 94 are disposed in a vicinity of the central electrode body 70. The two third magnets 93L and 93R are disposed to be symmetrical to each other in the slit width direction (x-direction) with the central electrode body 70 interposed therebetween (that is, with the central plane C interposed therebetween). On the other hand, the fourth magnet 94 is disposed on only one side with respect to the central electrode body 70 (that is, with respect to the central plane C). In the examples shown, the third magnet 93L and the fourth magnet 94 are disposed on the downstream side of the second magnet 92e disposed in a vicinity of the fifth side electrode body 80e. On the other hand, only the third magnet 93R is disposed on the downstream side of the second magnet 92f disposed in a vicinity of the sixth side electrode body 80f, and the fourth magnet is not disposed. As a result, the two third magnets 93L and 93R and the fourth magnet 94 apply a magnetic field having an asymmetrical distribution in the slit width direction with respect to the central plane C (refer to FIGS. 6 and 8 to be described later).

FIG. 6 is a view illustrating an example of a distribution of a magnetic field applied to each electrode body. In FIG. 6, the central electrode body 70 and the plurality of side electrode bodies 80 are shown with only outlines and without hatching such that the distribution of a magnetic field inside each electrode body is clearly shown. As illustrated, a magnetic field line extends in an arc shape from the first magnet 91 toward the second magnet 92. The magnetic field line that extends from the first magnet 91 toward the second magnet 92 bends around an axis extending in a direction perpendicular to the page of FIG. 6 (that is, the y-direction). The distribution of the magnetic field is configured such that a magnetic field line outgoing from the beam measurement surface 78 of the side electrode body 80 is incident into a surface of the same side electrode body 80, or the distribution of the magnetic field is configured such that a magnetic field line incident into the beam measurement surface 78 of the side electrode body 80 outgoes from a surface of the same side electrode body 80. In addition, the distribution of the magnetic field is configured such that a magnetic field line passing through a vicinity of the beam measurement surface 78 of the side electrode body 80 outgoes from a surface of the same side electrode body 80 and is incident into a surface of the same side electrode body 80.

FIG. 7 is a view illustrating an example of a distribution of a magnetic field applied to the side electrode body 80 in detail, and is an enlarged view of the vicinity of the first side electrode body 80a of FIG. 6. In FIG. 7, three magnetic field lines B1, B2, and B3 between the first magnet 91 and the second magnet 92 are shown as an example of the distribution of a magnetic field applied to the side electrode body 80. The magnetic field lines B1 to B3 outgoing from the first magnet 91 intersect the beam measurement surface 78 of the side electrode body 80, or pass through the vicinity of the beam measurement surface 78, and then are incident into the second magnet 92.

The first magnetic field line B1 passes through the upstream side extending portion 82, and outgoes from an inner side surface 86 of the upstream side extending portion 82. After traveling along the central plane C in the vicinity of an inner side surface 85 of the main body portion 81, which configures a part of the beam measurement surface 78, the first magnetic field line B1 is incident into an inner side surface 87 of the downstream side extending portion 83. After outgoing from the inner side surface 86 of the upstream side extending portion 82, the second magnetic field line B2 is incident into the inner side surface 85 of the main body portion 81 configuring a part of the beam measurement surface 78. After outgoing from the inner side surface 86 of the upstream side extending portion 82, the third magnetic field line B3 is incident into an upper surface 84 of the main body portion 81 configuring a part of the beam measurement surface 78. Herein, the upper surface 84 of the main body portion 81 is a surface exposed to the slit 66 (refer to FIGS. 4 to 6) on the upstream side in the beam traveling direction (z-direction). In addition, the inner side surfaces 85, 86, and 87 of the main body portion 81, the upstream side extending portion 82, and the downstream side extending portion 83 are surfaces exposed to the central plane C on an inner side in the slit width direction (x-direction), respectively.

By setting the illustrated distribution of a magnetic field, even in a case where secondary electrons are generated from the beam measurement surface 78 due to incidence of an ion beam, which is a measuring target, the secondary electrons are moved along spiral trajectories E1, E2, and E3 around the magnetic field lines B1, B2, and B3 respectively, and the secondary electrons can be incident into the inner side surfaces 86 and 87 of the same side electrode body 80. That is, the secondary electrons generated from the beam measurement surface 78 of the side electrode body 80 can be absorbed by the inner side surfaces 86 and 87 of the same side electrode body 80. As a result, it is possible to prevent that the secondary electrons are absorbed by another electrode body different from the electrode body where the secondary electrons are generated, charge movement between the electrode bodies different from each other occurs, and a measurement error is caused. In other words, by configuring the side electrode body 80 such that at least a part of the inner side surfaces 86 and 87 of the upstream side extending portion 82 and the downstream side extending portion 83of the side electrode body 80 becomes a secondary electron absorbing surface, the occurrence of a measurement error attributable to secondary electrons can be prevented.

Since secondary electrons moving along the magnetic field lines have the spiral trajectories as illustrated, it is preferable for the spiral trajectory E to have a small radius such that the secondary electrons are not incident into another side electrode body (for example, the second side electrode body 80b facing the first side electrode body 80a with the central plane C interposed therebetween) that is different from a side electrode body where the secondary electrons are generated (for example, the first side electrode body 80a). According to the findings of the inventors, the energy of secondary electrons generated from the beam measurement surface 78 due to the incidence of an ion beam is equal to or lower than 30 eV. Therefore, it is preferable to apply a magnetic field having a strength at which a Larmor radius of the spiral movement of electrons with the energy of 30 eV is smaller than a distance d₁ from the central plane C to the side electrode body 80.

In order to apply a distribution of a magnetic field illustrated in FIG. 7 to the side electrode body 80, it is necessary to appropriately set positions of the first magnet 91 and the second magnet 92 in the beam traveling direction (z-direction). It is necessary to dispose a center 95 of the first magnet 91 in the beam traveling direction (z-direction) to be at a position corresponding to the upstream side extending portion 82, that is, a position, which is on the upstream side of the beam measurement surface 78 and is on the downstream side of an upstream end 88 of the side electrode body 80. Similarly, it is necessary to dispose a center 96 of the second magnet 92 in the beam traveling direction (z-direction) to be at a position corresponding to the downstream side extending portion 83, that is, a position, which is on the downstream side of the beam measurement surface 78 and is on the upstream side of a downstream end 89 of the side electrode body 80. It is preferable to dispose the center 95 of the first magnet 91 close to the upstream end 88 than to the beam measurement surface 78. It is preferable to dispose the center 96 of the second magnet 92 close to the downstream end 89 than to the beam measurement surface 78. In addition, it is preferable that a midpoint between the first magnet 91 and the second magnet 92 in the beam traveling direction (z-direction) match a position of the beam measurement surface 78 in the beam traveling direction (z-direction).

In the side electrode body 80 of the embodiment, since the length of the main body portion 81 protruding toward the central plane C in the beam traveling direction (z-direction) is small, a range of the beam measurement surface 78 in the beam traveling direction (z-direction) can be made small, and thus a place where secondary electrons can be generated (that is, the beam measurement surface 78) can be limited. In other words, by making distances d₂ and d₃ from the central plane C to the upstream side extending portion 82 and the downstream side extending portion 83 larger than the distance d₁ from the central plane C to the main body portion 81, at least a part of the inner side surface 86 of the upstream side extending portion 82 and the entire inner side surface 87 of the downstream side extending portion 83 can be set as “beam non-irradiation surface” which is not irradiated with a beam. In addition, at least a part of the inner side surfaces 86 and 87 of the upstream side extending portion 82 and the downstream side extending portion 83 can be set as a “secondary electron absorbing surface” which absorbs secondary electrons generated from the beam measurement surface 78. By making the lengths of the upstream side extending portion 82 and the downstream side extending portion 83 in the beam traveling direction (z-direction) larger than the length of the main body portion 81 in the ion beam traveling direction (z-direction), a range that becomes the “beam non-irradiation surface” and the “secondary electron absorbing surface” can be made large in the beam traveling direction (z-direction), and thus secondary electrons generated from the beam measurement surface 78 can be reliably absorbed by the upstream side extending portion 82 and the downstream side extending portion 83.

In addition, secondary electrons directed from the beam measurement surface 78 toward the downstream side can be efficiently absorbed by the inner side surface 87 of the downstream side extending portion 83 by making the distance d₃ from the central plane C to the downstream side extending portion 83 larger than the distance d₂ from the central plane C to the upstream side extending portion 82 and making the inner side surface 87 of the downstream side extending portion 83 closer to the beam measurement surface 78 (the inner side surface 85 of the main body portion 81) to an extent possible. It is necessary to make the distance d₃ from the central plane C to the downstream side extending portion 83 large to an extent that the entire inner side surface 87 of the downstream side extending portion 83 becomes the “beam non-irradiation surface”, that is, to an extent that the entire inner side surface 87 of the downstream side extending portion 83 is hidden behind the main body portion 81.

FIG. 8 is a view illustrating an example of a distribution of a magnetic field applied to the central electrode body 70 in detail, and is an enlarged view of the vicinity of the central electrode body 70 of FIG. 6. In FIG. 8, three magnetic field lines B4, B5 and B6 between the two third magnets 93L and 93R and the fourth magnet 94 are shown as an example of the distribution of a magnetic field applied to the central electrode body 70. The distribution of a magnetic field of the vicinity of the central electrode body 70 is asymmetrical with respect to the central plane C in the slit width direction (x-direction) as illustrated. For example, after outgoing from the third magnet 93R, the fourth magnetic field line B4 intersecting the beam measurement surface 74 (the surface of the base portion 71) passes through the extending portion 72R to outgo from an inner side surface 73R of the extending portion 72R, and is incident into the beam measurement surface 74. After then, the fourth magnetic field line B4 passes through the base portion 71 and is incident into the fourth magnet 94.

Secondary electrons generated from the beam measurement surface 74 of the central electrode body 70 move along a spiral trajectory E4 around the fourth magnetic field line B4 and is incident into the inner side surface 73R of the extending portion 72R. Therefore, at least a part of the inner side surface 73R of the extending portion 72R becomes the “beam non-irradiation surface” and the “secondary electron absorbing surface”. By setting the asymmetrical distribution of a magnetic field as illustrated, the secondary electrons generated from the beam measurement surface 74 can be incident into the inner side surface 73R of the extending portion 72R which is one of the extending portions of the central electrode body 70. In a case of setting a symmetrical distribution of a magnetic field with respect to the central plane C in the slit width direction (x-direction), a magnetic field line extends in a direction along the central plane C in a vicinity of the central plane C. Thus, there is a possibility that secondary electrons generated from the beam measurement surface 74 escape to the upstream side of the central electrode body 70 along the central plane C. Then, the secondary electrons generated from the central electrode body 70 may be absorbed by the side electrode body 80 (for example, the fifth side electrode body 80e or the sixth side electrode body 80f) positioned on the upstream side of the central electrode body 70, and thus a possibility of resulting in a measurement error occurs. On the contrary, since the distribution of a magnetic field applied to the central electrode body 70 is asymmetrical in the embodiment, secondary electrons generated in the vicinity of the central plane C can be reliably absorbed by the inner side surface 73R of the extending portion 72R which is one of the extending portions.

In order to apply the distribution of a magnetic field illustrated in FIG. 8 to the central electrode body 70, it is necessary to dispose the third magnets 93L and 93R in the beam traveling direction (z-direction) to be at positions corresponding to the extending portions 72L and 72R, that is, positions, which are on the upstream side of the beam measurement surface 74 and are on the downstream side of an upstream end 75 of the central electrode body 70. It is preferable to dispose centers 97L and 97R of the third magnets 93L and 93R in the beam traveling direction (z-direction) close to the upstream end 75 than to the beam measurement surface 74. On the other hand, it is necessary to dispose the fourth magnet 94 on downstream side of the beam measurement surface 74, and it is preferable to dispose a center 98 of the fourth magnet 94 in the beam traveling direction (z-direction) on the downstream side of the beam measurement surface 74.

The measuring device 62 having the configuration can measure an angle component of an ion beam, which has passed through the slit 66, in the slit width direction (x-direction) by using the central electrode body 70 and the plurality of side electrode bodies 80. Since a distribution of a magnetic field applied to the plurality of side electrode bodies 80 is symmetrical with respect to the central plane C in the slit width direction, a magnetic field line in the vicinity of the central plane C extends in the direction along the central plane C. As a result, an effect of a change in a trajectory of an ion beam passing through the vicinity of the central plane C caused by the application of the magnetic field can be made small, and a measurement error caused by the beam trajectory change can be prevented from occurring. On the other hand, since a distribution of a magnetic field applied to the central electrode body 70 is asymmetrical with respect to the central plane C in the slit width direction, there is a possibility of affecting the trajectory of an ion beam passing through the vicinity of the central plane C. However, since all beams passing through the vicinity of the central electrode body 70 can be detected by the central electrode body 70, a measurement error does not occur. Therefore, in the embodiment, by applying a magnetic field to each electrode body, the occurrence of a measurement error attributable to secondary electrons can be suitably prevented, and the measurement accuracy of an angle distribution of an ion beam can be improved.

It should be understood that the invention is not limited to the above-described embodiment, but may be modified into various forms on the basis of the spirit of the invention. Additionally, the modifications are included in the scope of the invention. In addition, it is also possible to add rearrangement of combinations or procedures of processing as appropriate in each embodiment based on knowledge of those skilled in the art or a modification such as various types of design changes to the embodiment, and an embodiment to which such a modification is added can also be included in the scope of the present invention.

In the embodiment described above, a negative voltage with respect to an electric potential (for example, a ground electric potential) of the housing 64 (the slit 66) may be applied to the central electrode body 70 and the plurality of side electrode bodies 80. An absolute value of a negative bias voltage applied to the central electrode body 70 and the plurality of side electrode bodies 80 maybe equal to or higher than 30V. That is, the negative bias voltage may be equal to or lower than −30 V. For example, in a case where energy of an ion beam, which is a measuring target, is EB and charge of an ion is q, a negative bias voltage of which an absolute value is approximately EB/q×0.1 may be applied. By applying the negative bias voltage to the central electrode body 70 and the plurality of side electrode bodies 80, it is possible to suitably prevent secondary electrons, which are generated from the inner surface of the angle restricting unit 64c due to the incidence of an ion beam, from flowing into at least any one of the central electrode body 70 and the plurality of side electrode bodies 80. Accordingly, the measurement accuracy of the measuring device 62 can be further improved.

In embodiment described above, a configuration where a magnetic field is applied to all of the central electrode body 70 and the plurality of side electrode bodies 80 is adopted. A configuration where a magnetic field is applied to only a part of the central electrode body 70 and the plurality of side electrode bodies 80 maybe adopted as a modification example. For example, a magnetic field may be applied to only some electrode bodies in which a measurement error caused by the generation of secondary electrons is conspicuous.

It should be understood that the invention is not limited to the above-described embodiment, but may be modified into various forms on the basis of the spirit of the invention. Additionally, the modifications are included in the scope of the invention.

What is claimed is:

1. An ion implanter that includes a measuring device that measures an angle distribution of an ion beam with which a wafer is irradiated, the measuring device comprising:
a slit into which the ion beam is incident;
a central electrode body that includes a beam measurement surface which is disposed on a central plane extending from the slit to a beam traveling direction, the central plane serving as reference of the ion beam;
a plurality of side electrode bodies that are disposed between the slit and the central electrode body and disposed to be away from the central plane in a slit width direction of the slit, wherein each of the plurality of side electrode bodies has a beam measurement surface; and
a magnet device that applies a magnetic field bending around an axis extending along a slit length direction of the slit to at least one of the beam measurement surfaces of the plurality of side electrode bodies.

2. The ion implanter according to claim 1,
wherein the magnet device applies the magnetic field such that a magnetic field line outgoing from at least one of the beam measurement surfaces of the plurality of side electrode bodies is incident into a surface of the same side electrode body, or such that a magnetic field line incident into at least one of the beam measurement surfaces of the plurality of side electrode bodies outgoes from a surface of the same side electrode body.

3. The ion implanter according to claim 1,
wherein a strength of the magnetic field applied to at least one of the beam measurement surfaces of the plurality of side electrode bodies is determined such that a Larmor radius of a secondary electron generated from the beam measurement surface by incidence of the ion beam is smaller than a distance from the beam measurement surface to the central plane.

4. The ion implanter according to claim 1,
wherein the magnet device includes a first magnetic pole that is disposed on an upstream side of at least one of the beam measurement surfaces of the plurality of side electrode bodies in the beam traveling direction and a second magnetic pole that is disposed on a downstream side of the at least one of the beam measurement surfaces of the plurality of side electrode bodies in the beam traveling direction and has a polarity different from a polarity of the first magnetic pole, and applies the magnetic field such that at least a part of magnetic field lines between the first magnetic pole and the second magnetic pole intersects a beam measurement surface of a corresponding side electrode body.

5. The ion implanter according to claim 4,
wherein a center of the first magnetic pole in the beam traveling direction is positioned closer to an upstream end of the corresponding side electrode body than to the beam measurement surface of the corresponding side electrode body, and a center of the second magnetic pole in the beam traveling direction is positioned closer to a downstream end of the corresponding side electrode body than to the beam measurement surface of the corresponding side electrode body.

6. The ion implanter according to claim 5,
wherein the center of the first magnetic pole in the beam traveling direction is positioned on the downstream side of the upstream end of the corresponding side electrode body, and the center of the second magnetic pole in the beam traveling direction is positioned on the upstream side of the downstream end of the corresponding side electrode body.

7. The ion implanter according to claim 4,
wherein the first magnetic pole and the second magnetic pole are disposed to be further away from the central plane in the slit width direction than the plurality of side electrode bodies are.

8. The ion implanter according to claim 1,
wherein the plurality of side electrode bodies include a first group of side electrode bodies arranged in the beam traveling direction and a second group of side electrode bodies disposed to be symmetrical to the first group of side electrode bodies in the slit width direction with the central plane interposed therebetween, and
the magnet device applies the magnetic field such that a distribution of the magnetic field applied to the first group of side electrode bodies and a distribution of the magnetic field applied to the second group of side electrode bodies are symmetrical to each other in the slit width direction with the central plane interposed therebetween.

9. The ion implanter according to claim 1,
wherein the magnet device applies the magnetic field such that a magnetic field line on the central plane is directed along the central plane.

10. The ion implanter according to claim 1,
wherein each of the plurality of side electrode bodies includes a main body portion including at least a part of the beam measurement surface, an upstream side extending portion that extends from the main body portion to an upstream side in the beam traveling direction, and a downstream side extending portion that extends from the main body portion to a downstream side in the beam traveling direction, and
a distance from each of the upstream side extending portion and the downstream side extending portion to the central plane in the slit width direction is larger than a distance from the main body portion to the central plane in the slit width direction.

11. The ion implanter according to claim 10,
wherein the distance from the downstream side extending portion to the central plane in the slit width direction is smaller than the distance from the upstream side extending portion to the central plane in the slit width direction.

12. The ion implanter according to claim 10,
wherein a length of each of the upstream side extending portion and the downstream side extending portion in the beam traveling direction is larger than a length of the main body portion in the beam traveling direction.

13. The ion implanter according to claim 10,
wherein the beam measurement surface on the main body portion includes an upper surface exposed to the slit along the beam traveling direction and an inner side surface exposed to the central plane along the slit width direction.

14. The ion implanter according to claim 10,
wherein at least a part of an inner side surface of the upstream side extending portion, which is exposed to the central plane, is a beam non-irradiation surface where incidence of an ion beam, which has passed through the slit, is blocked by a structure on the upstream side of the upstream side extending portion, and a secondary electron absorbing surface into which a secondary electron generated from the beam measurement surface is incident.

15. The ion implanter according to claim 10,
wherein at least a part of an inner side surface of the downstream side extending portion, which is exposed to the central plane, is a beam non-irradiation surface where incidence of an ion beam, which has passed through the slit, is blocked by the main body portion, and a secondary electron absorbing surface into which a secondary electron generated from the beam measurement surface is incident.

16. The ion implanter according to claim 1,
wherein the magnet device applies the magnetic field such that a distribution of the magnetic field applied to the beam measurement surface of the central electrode body has an asymmetrical property in the slit width direction with the central plane as a reference plane.

17. The ion implanter according to claim 16,
wherein the central electrode body includes a base portion including the beam measurement surface exposed to the slit along the beam traveling direction and a pair of extending portions which respectively extend from both ends of the base portion in the slit width direction to an upstream side in the beam traveling direction, and
the magnet device applies the magnetic field such that a magnetic field line outgoing from the beam measurement surface of the base portion is incident into one of surfaces of the pair of extending portions or such that a magnetic field line incident into the beam measurement surface of the base portion outgoes from one of surfaces of the pair of extending portions.

18. The ion implanter according to claim 1,
wherein the measuring device further includes a bias power supply that applies a negative voltage to the central electrode body and the plurality of side electrode bodies with an electric potential of the slit as reference.

19. A measuring device that measures an angle distribution of an ion beam, the measuring device comprising:
a slit into which the ion beam is incident;
a central electrode body that includes a beam measurement surface which is disposed on a central plane extending from the slit to a beam traveling direction, the central plane serving as reference of the ion beam;
a plurality of side electrode bodies that are disposed between the slit and the central electrode body and disposed to be away from the central plane in a slit width direction of the slit, wherein each of the plurality of side electrode bodies has a beam measurement surface; and
a magnet device that applies a magnetic field bending around an axis extending along a slit length direction of the slit to at least one of the beam measurement surfaces of the plurality of side electrode bodies.
